(19) United States
(12) Patent Application Publication
(10) Pub. No.: US 2022/0093480 A1
(43) Pub. Date: Mar. 24, 2022

(54) MOLD-IN-MOLD STRUCTURE TO IMPROVE SOLDER JOINT RELIABILITY

(71) Applicant: Intel Corporation, Santa Clara, CA (US)

(72) Inventor: Krishna Hemanth VEPAKOMMA, El Dorado Hills, CA (US)

(21) Appl. No.: 17/031,816

(22) Filed: Sep. 24, 2020

(51) Int. Cl. H01L 23/31; H01L 23/00; H01L 25/065; H01L 25/00; H01L 21/56

(52) U.S. Cl. CPC H01L 23/3135; H01L 24/13; H01L 25/0652; H01L 2924/3512; H01L 21/565; H01L 24/45; H01L 25/50

(57) ABSTRACT

A semiconductor package comprises a substrate having a first side and the second side, the second side comprising interconnect joints. One or more die stacks are over the first side of the substrate. An inner mold material having a low Young's modulus of less than 2500 MPa encapsulates the one or more die stacks. An outer mold material having a higher Young's modulus encapsulates the inner mold material.

### TECHNICAL FIELD

Embodiments of the disclosure are in the field of semiconductor package and, in particular, a mold-in-mold structure to improve solder joint reliability.

### BACKGROUND

Today's consumer electronics market frequently demands complex functions requiring very intricate circuitry. Scaling to smaller and smaller fundamental building blocks, e.g. transistors, has enabled the incorporation of even more intricate circuitry on a single die with each progressive generation. Semiconductor packages are used for protecting an integrated circuit (IC) chip or die, and also to provide the die with an electrical interface to external circuitry. With the increasing demand for smaller electronic devices, semiconductor packages are designed to be even more compact and must support larger circuit density, which in some cases may affect solder joint reliability.

For example, some semiconductor packages, such ball grid array (BGA) packages, may comprise a substrate, a die stack on the substrate, wire bonds coupling the die stack to the substrate, a mold material encapsulating the die stack and the wire bonds, and pads on a backside of the substrate to connect with other devices. The differing coefficients of thermal expansion (CTEs) of the substrate, the die stack, and the molding compound can create stress in the package caused by coefficient of thermal expansion (CTE) mismatches within the package. This can negatively affect the solder joint used to couple the package's pad to another the pad of another semiconductor package or a printed circuit board (PCB). This stress can cause cracks in the interconnect joint, cratering of the pads, etc.

Previous solutions to solve the problem include increasing solder resist openings and reducing die size. Sometime approaches place a bottom spacer between the die and the substrate, but results in an added expense. In addition, little improvement can be made through material choices, as the materials inside the package have already been optimized to get the most solder joint reliability (SJR).

Consequently, due to the nature of the problem, semiconductor manufacturers spend enormous resources to manage SJR, using for example, thermal cycling to test the reliability of the solder joints in BGA packages, especially NAND and 3D XPoint memory packages.

### BRIEF DESCRIPTION OF THE DRAWINGS

FIG. 1 is a diagram illustrating a cross-section view of a packaged system with a stacked die structure.

FIG. 2 is a diagram illustrating a cross-section view of a package system comprising a semiconductor package having a mold-in-mold structure in accordance with the disclosed embodiments.

FIGS. 3A-3C illustrate a process for fabricating a semiconductor package having a mold-in-mold structure.

FIG. 4 is a cross-sectional side view of an integrated circuit (IC) device assembly that may include a mold-in-mold structure for improving solder joint reliability, in accordance with one or more of the embodiments disclosed herein.

FIG. 5 illustrates a computing device in accordance with one implementation of the disclosure.

### DESCRIPTION OF THE EMBODIMENTS

Embodiments of a mold-in-mold structure to improve solder joint reliability are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

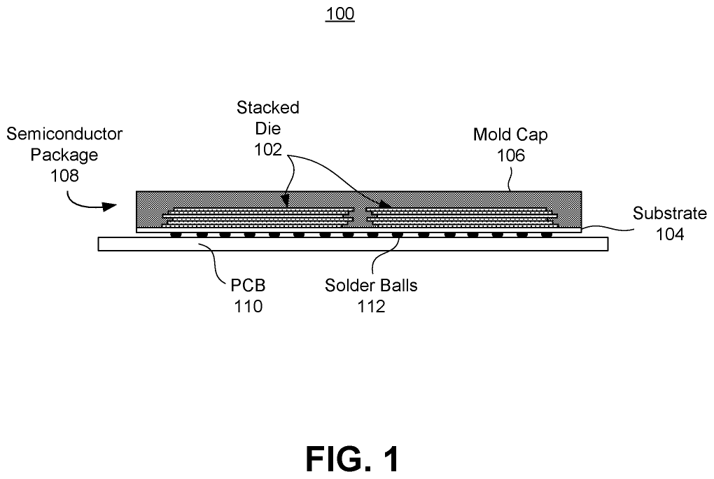

One or more embodiments described herein are directed to a mold-in-mold structure to improve solder joint reliability in semiconductor packages. To provide context, FIG. 1 is a diagram illustrating a cross-section view of a packaged system with a stacked die structure. As shown, the packaged system 100 includes stacked die 102 attached to a mold carrier or a substrate 104. A rigid mold cap 106 is formed over the stacked die 102 and the substrate 104 to form a semiconductor package 108. The semiconductor package 108 is attached to a board 110 (e.g., a PCB) with solder balls 112 or any type of interconnect architecture.

As described above, CTE mismatch between different materials comprising the package system 100 cause stresses in solder joints, which eventually fatigue and fail. As the z-height and complexity of die stacks increase, there is a need to improve solder joint reliability (SJR).

According to the disclosed embodiments, an additional low-modulus mold material is added within a mold cap that encapsulates die-stacks to aid the die-stacks in expanding or contracting more freely. The disclosed embodiments provide a semiconductor package comprising a substrate having a first side and the second side, the second side comprising interconnect joints. One or more die stacks are over the first side of the substrate. An inner mold material having a low Young's modulus of less than 2500 MPa encapsulates the stacks. An outer mold material having a higher Young's modulus encapsulates the inner mold material to provide a mold-in-mold structure. Such a mold-in-mold structure reduces the stress on interconnect joints, such as solder balls, which increases the life span of the interconnects.

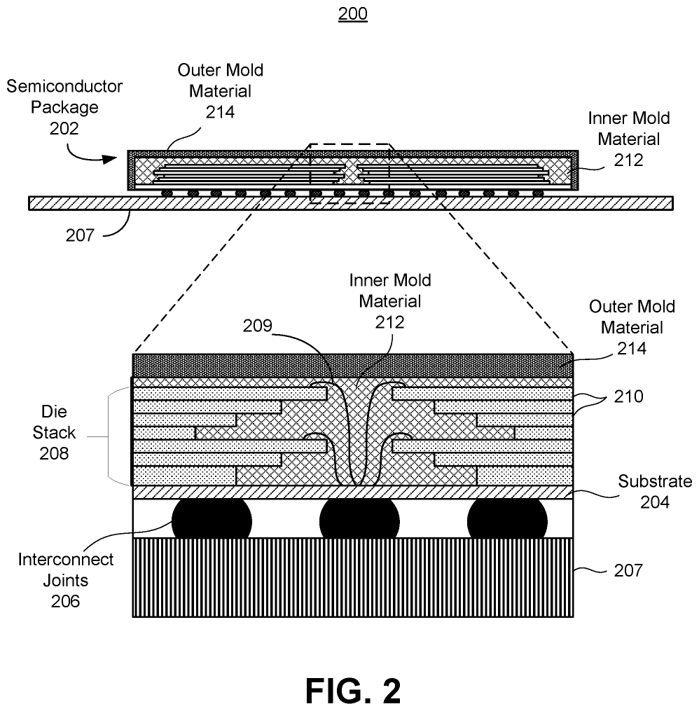

FIG. 2 is a diagram illustrating a cross-section view of a package system 200 comprising a semiconductor package having a mold-in-mold structure in accordance with the disclosed embodiments. An enlarged view of a portion of the package system 200 enclosed in a dashed box is also shown in FIG. 2. In embodiments, the package 200 comprises a semiconductor package 202 comprising a substrate 204 (e.g., a BGA substrate) having a first side and the second side, where the second side includes interconnect joints 206. One or more die stacks 208 are over the first side of the substrate 204. The substrate 204 may comprise any known substrate in the art. For example, an organic substrate, an inorganic substrate (e.g., ceramic substrate, silicon substrate, etc.), a combination of an organic substrate and an inorganic substrate, etc.

Each of the die stacks 208 comprise one or more die 210 attached to other die using die attach films (not shown). The die attach film can be formed from an epoxy adhesive for example. The package 202 also includes wire bonds 209 for coupling the dies 210 to the substrate 204. The wire bonds 209 can be formed from copper or any other conductive materials known in the art. In an embodiment, the dies 210 may be offset from each other in order to provide access to the top surface of each of the dies 210 to allow for wire bonding from the top surface of the dies to the substrate 204. In embodiments, the semiconductor package 202 may include other components other than one or more die stacks 208, such as for example, an application-specific integrated circuit (ASIC) or integrated microelectromechanical systems (MEMS).

The interconnect joints 206 or any type of interconnect architecture couples the semiconductor package 202 to a board 207 (e.g., a printed circuit board (PCB)) or like receiving structure. The interconnect joints 206 can be solder bumps, gold bumps, conductive epoxy bumps, copper bumps, column-shaped bumps, spring-type connections, any other suitable interconnect joint known in the art (e.g., a pin grid array, a land grid array, etc.), or any combination thereof.

According to the disclosed embodiments, an inner mold material 212 having a low Young's modulus of less than 2500 Mpa is used to encapsulate the die stacks 208 (including the wire bonds 209 and die attach films), and an outer mold material 214 having a higher Young's modulus is used to encapsulate the inner mold material 212 to provide a mold-in-mold structure. The inner mold material 212 may have a low Young's modulus of 2500 Mpa or less over a temperature range of −50° C. to 270° C. The higher Young's modulus of the outer mold material 214 is at least approximately 20,000 MPa in embodiments. The coefficient of thermal expansion of the inner mold material 212 is not of significant importance to improving SJR.

In a further aspect of the disclosed embodiments, different ranges of the Young's modulus of the inner mold material 212 between 1 and 2500 MPa may be used to provide different ranges of SIR protection, where the higher the Young's modulus the lower the benefit. For example, the low Young's modulus of the inner mold material 212 may range from approximately 1 to 500 MPa to provide the greatest improvement in SJR. The low Young's modulus may range from approximately 501 to 1500 MPa to provide an intermediate improvement in SJR. The low Young's modulus may range from approximately 1501 to 2500 MPa to provide an incremental improvement in SJR. According to embodiments, using an inner mold material 212 having a Young's modulus of 500 MPa or less improves SJR by approximately 10 times using existing manufacturing processes and materials.

The mold-in-mold structure formed by the inner mold material 212 and the outer mold material 214 to improve solder joint reliability provides many advantages. The inner mold material 212 separates the outer mold material 214 from the die stacks 208 and absorbs stress that results from a CTE mismatch between the outer mold material 214 and die stacks 208. Absorption of the stress by the inner mold material 212 assists with reducing the amount of stress transferred to the interconnect joints 206 and with minimizing or eliminating the occurrence of delamination within the package. In this way, interconnect joint reliability (e.g., SJR) may be improved. The inner mold material 212 is able to absorb the stress within the package system 200 because the inner mold material 212 has a Young's modulus that is lower than a Young's modulus of the outer mold material 214. By absorbing the stress, the inner mold material 212 also enables fabrication of semiconductor packages that lack spacers and polyimide layers, which in turn reduces costs associated with semiconductor packaging.

In embodiments, the inner mold material 212 may comprise a soft material, while the outer mold material 214 may comprise a rigid material. The inner mold material 212 may can be any material that can be patterned. One example of such a material is a photoresist (e.g., photopolymeric photoresist, photodecomposing photoresist, photocrosslinking photoresist, self-assembled monolayer photoresist, and the like). In another embodiment, the material may include die attach film (DAF), such as KER-6020-F having a Young's Modulus of 6-21 Mpa over a temperature of −60 to 150° C.; DA7920 having a Young's Modulus of 1-30 Mpa over a temperature of −40 to 200° C.; and EM-770J1-P having a Young's Modulus of 1.1 Mpa (DMA 50° C.). In yet another embodiment, the material may include a glob top compound such as SMP-5008 having a Young's Modulus of 0-200 Mpa over a temperature of −50 to 190° C.

The thickness of the inner mold material 212 is application specific and depends on the z-height of the die stacks 208. In one embodiment, the outer mold material 214 may comprise epoxy resin or any other suitable material known in the art. The outer mold material 214 is at least approximately 0.1 mm in thickness in some embodiments.

In FIG. 2, although the inner mold material 212 is shown encapsulating all the die stacks 208, not all components of the semiconductor package 202 need to be embedded in the same material or a material having a same property. For example, one type of component could be embedded within one type of inner mold material having a different Young's modulus than another type of inner mold material embedding other components.

In yet another embodiment, the inner mold material 212 and/or the outer mold material 214 may be formed with more than one layer, where a first layer has a different Young's modulus than a second layer.

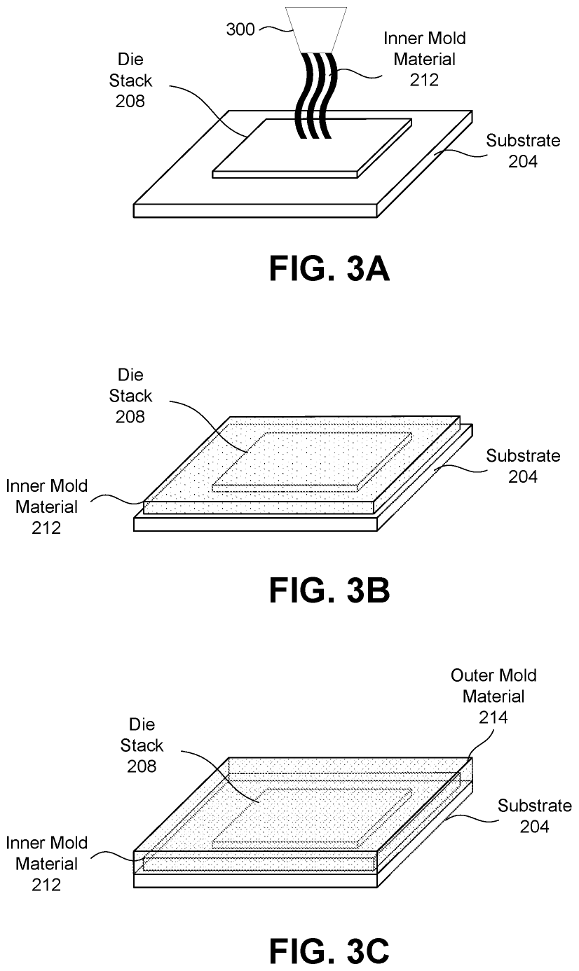

FIGS. 3A-3C illustrate a process for fabricating a semiconductor package having a mold-in-mold structure. FIG. 3A illustrates the fabrication process after one or more die stacks 208 are formed and coupled to the substrate 204. In an embodiment, each die stack 208 comprises multiple dies stacked on one another. A pick and place machine may be used to place the die stack 208 on the substrate 204. The substrate 204 may be formed from organic materials, inorganic materials, or any combination thereof. Next, the inner mold material 212 having a low Young's modulus of less than 2500 MPa is formed to encapsulate the one or more die stacks 208 and the substrate 204. The inner mold material 212 encapsulate the top and lateral sides of the die stacks 208. The inner mold material 212 can be formed, for example, by dispensing via a dispenser 300, molding, lamination or printing. For example, a spin coating technique may be used to coat the die stack 208 and the substrate 204. In one such embodiment, a soft material is used for the embedding of the die stacks 208.

FIG. 3B shows the process after the inner mold material 212 is patterned or cut away from edges of the substrate 204 to leave room for the outer mold material 214. For example, the inner mold material 212 may be lithographically patterned. In one embodiment, the inner mold material 212 is cut away from edges of the substrate 204 a distance at least equal to the intended thickness of the outer mold material 214. Rather than cover an entire area of the substrate 204, in another embodiment, the mold material 212 may be patterned to only cover individual die stacks 208, leaving remaining areas of the substrate 204 open.

FIG. 3C shows the process after an outer mold material 214 having a higher Young's modulus is formed to encapsulate the inner mold material 212 and the substrate 204. The outer mold material 214 may be deposited along a top and sidewalls of the inner mold material 212.

In one embodiment, the process may further include attaching interconnect joints to a bottom side of the substrate 204. In the embodiment, where the inner mold material 212 is patterned to only cover individual ones of the die stacks 208, the process may further include enticing the die stacks such that portions of the outer mold material 214 are removed (e.g. with a saw or laser) between the die stacks 208 to provide singulated packages (not shown). The interconnect joints may then be attached to the bottom side of the substrates of the diced die stacks to form semiconductor packages.

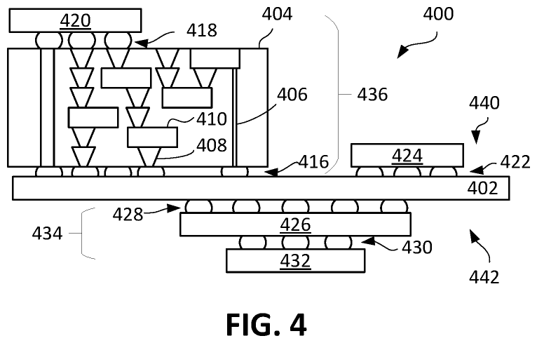

FIG. 4 is a cross-sectional side view of an integrated circuit (IC) device assembly that may include a mold-in-mold structure for improving solder joint reliability, in accordance with one or more of the embodiments disclosed herein.

Referring to FIG. 4, an IC device assembly 400 includes components having one or more integrated circuit structures described herein. The IC device assembly 400 includes a number of components disposed on a circuit board 402 (which may be, e.g., a motherboard). The IC device assembly 400 includes components disposed on a first face 440 of the circuit board 402 and an opposing second face 442 of the circuit board 402. Generally, components may be disposed on one or both faces 440 and 442. In particular, any suitable ones of the components of the IC device assembly 400 may include a number of RF filters fabricated on a semiconductor package using selective seeding, such as disclosed herein.

In some embodiments, the circuit board 402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 402. In other embodiments, the circuit board 402 may be a non-PCB substrate.

The IC device assembly 400 illustrated in FIG. 4 includes a package-on-interposer structure 436 coupled to the first face 440 of the circuit board 402 by coupling components 416. The coupling components 416 may electrically and mechanically couple the package-on-interposer structure 436 to the circuit board 402, and may include solder balls (as shown in FIG. 4), male and female portions of a socket, an adhesive, an underfill material, and/or any other suitable electrical and/or mechanical coupling structure.

The package-on-interposer structure 436 may include an IC package 420 coupled to an interposer 404 by coupling components 418. The coupling components 418 may take any suitable form for the application, such as the forms discussed above with reference to the coupling components 416. Although a single IC package 420 is shown in FIG. 4, multiple IC packages may be coupled to the interposer 404. It is to be appreciated that additional interposers may be coupled to the interposer 404. The interposer 404 may provide an intervening substrate used to bridge the circuit board 402 and the IC package 420. The IC package 420 may be or include, for example, a die or any other suitable component. Generally, the interposer 404 may spread a connection to a wider pitch or reroute a connection to a different connection. For example, the interposer 404 may couple the IC package 420 (e.g., a die) to a ball grid array (BGA) of the coupling components 416 for coupling to the circuit board 402. In the embodiment illustrated in FIG. 4, the IC package 420 and the circuit board 402 are attached to opposing sides of the interposer 404. In other embodiments, the IC package 420 and the circuit board 402 may be attached to a same side of the interposer 404. In some embodiments, three or more components may be interconnected by way of the interposer 404.

The interposer 404 may be formed of an epoxy resin, a fiberglass-reinforced epoxy resin, a ceramic material, or a polymer material such as polyimide. In some implementations, the interposer 404 may be formed of alternate rigid or flexible materials that may include the same materials described above for use in a semiconductor substrate, such as silicon, germanium, and other group III-V and group IV materials. The interposer 404 may include metal interconnects 410 and vias 408, including but not limited to through-silicon vias (TSVs) 406. The interposer 404 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 404. The package-on-interposer structure 436 may take the form of any of the package-on-interposer structures known in the art.

The IC device assembly 400 may include an IC package 424 coupled to the first face 440 of the circuit board 402 by coupling components 422. The coupling components 422 may take the form of any of the embodiments discussed above with reference to the coupling components 416, and the IC package 424 may take the form of any of the embodiments discussed above with reference to the IC package 420.

The IC device assembly 400 illustrated in FIG. 4 includes a package-on-package structure 434 coupled to the second face 442 of the circuit board 402 by coupling components 428. The package-on-package structure 434 may include an IC package 426 and an IC package 432 coupled together by coupling components 430 such that the IC package 426 is disposed between the circuit board 402 and the IC package 432. The coupling components 428 and 430 may take the form of any of the embodiments of the coupling components 416 discussed above, and the IC packages 426 and 432 may take the form of any of the embodiments of the IC package 420 discussed above. The package-on-package structure 434 may be configured in accordance with any of the package-on-package structures known in the art.

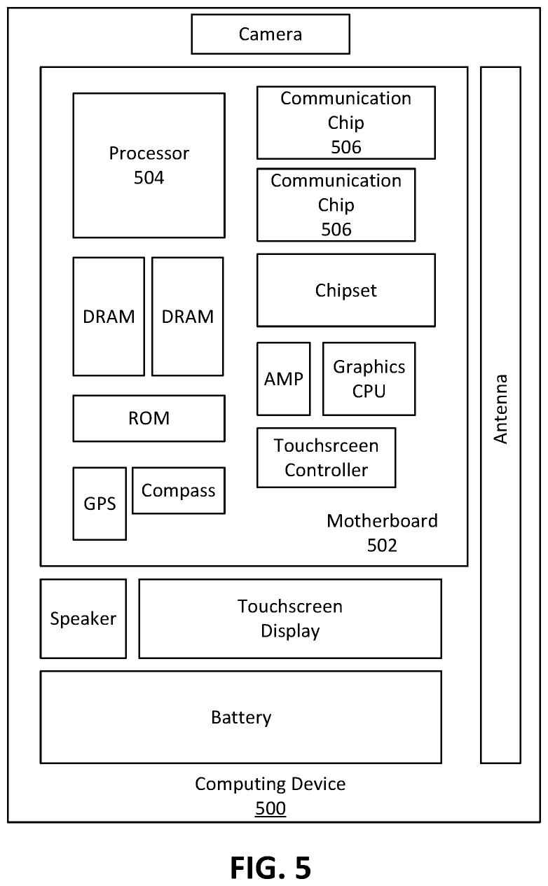

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor includes a mold-in-mold structure for improving solder joint reliability, in accordance with implementations of embodiments of the disclosure. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of embodiments of the disclosure, the integrated circuit die of the communication chip includes a mold-in-mold structure for improving solder joint reliability, in accordance with implementations of embodiments of the disclosure.

In further implementations, another component housed within the computing device 500 may contain an integrated circuit die that includes a mold-in-mold structure for improving solder joint reliability, in accordance with implementations of embodiments of the disclosure.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Thus, embodiments described herein include a mold-in-mold structure to improve sold or joint reliability in semiconductor packages.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A semiconductor package comprises a substrate having a first side and the second side, the second side comprising interconnect joints. One or more die stacks are over the first side of the substrate. An inner mold material having a low Young's modulus of less than 2500 MPa encapsulates the one or more die stacks. An outer mold material having a higher Young's modulus encapsulates the inner mold material.

Example embodiment 2: The semiconductor package of embodiment 1, wherein the low Young's modulus of the inner mold material is approximately 2500 MPa or less over a temperature range of −50° C. to 270° C.

Example embodiment 3: The semiconductor package of embodiment 1 or 2, wherein the low Young's modulus of the inner mold material ranges from approximately 1 to 500 MPa.

Example embodiment 4: The semiconductor package of embodiment 1, 2 or 3, wherein the inner mold material improves solder joint reliability by approximately 10 times.

Example embodiment 5: The semiconductor package of embodiment 1, wherein the low Young's modulus of the inner mold material ranges from approximately 501 to 1500 MPa.

Example embodiment 6: The semiconductor package of embodiment 1, wherein the low Young's modulus of the inner mold material ranges from approximately 1501 to 2500 MPa.

Example embodiment 7: The semiconductor package of embodiment 1, 2, 3, 4, 5, or 6, wherein the higher Young's modulus of the outer mold material is approximately at least 20,000 MPa.

Example embodiment 8: The semiconductor package of embodiment 1, 2, 3, 4, 5, 6 or 7, wherein the outer mold material is at least approximately 0.1 mm in thickness.

Example embodiment 9: The semiconductor package of embodiment 1, 2, 3, 4, 5, 6, 7, wherein the inner mold material comprises one of: a photopolymeric photoresist, a photodecomposing photoresist, a photocrosslinking photoresist, a self-assembled monolayer photoresist, a die attach film, and a glob top compound.

Example embodiment 10: A package system comprises a printed circuit board and a semiconductor package. The semiconductor package comprises a substrate having a first side and the second side, the second side comprising an array of solder balls to couple the semiconductor package to printed circuit board. One or more die stacks are over the first side of the substrate. An inner mold material having a low Young's modulus of less than 2500 MPa encapsulates the one or more die stacks. An outer mold material having a higher Young's modulus encapsulates the inner mold material.

Example embodiment 11: The package system of embodiment 10, wherein the low Young's modulus of the inner mold material is approximately 2500 MPa or less over a temperature range of −50° C. to 270° C.

Example embodiment 12: The package system of embodiment 10, wherein the low Young's modulus of the inner mold material ranges from approximately 1 to 500 MPa.

Example embodiment 13: The package system of embodiment 10, 11, or 12, wherein the inner mold material improves solder joint reliability by approximately 10 times.

Example embodiment 14: The package system of embodiment 10, wherein the low Young's modulus of the inner mold material ranges from approximately 501 to 1500 MPa.

Example embodiment 15: The package system of embodiment 10, wherein the low Young's modulus of the inner mold material ranges from approximately 1501 to 2500 MPa.

Example embodiment 16: The package system of embodiment 10, 11, 12, 13, 14 or 15, wherein the higher Young's modulus of the outer mold material is approximately at least 20,000 MPa.

Example embodiment 17: The package system of embodiment 10, 11, 12, 13, 14, 15 or 16, wherein the outer mold material is at least approximately 0.1 mm in thickness.

Example embodiment 18: The package system of embodiment 10, 11, 12, 13, 14, 15, 16 or 17, wherein the inner mold material comprises one of: a photopolymeric photoresist, a photodecomposing photoresist, a photocrosslinking photoresist, a self-assembled monolayer photoresist, a die attach film, and a glob top compound.

Example embodiment 19: A method of fabricating a semiconductor package, comprises forming one or more die stacks over a first side of the substrate. An inner mold material having a low Young's modulus of less than 2500 MPa is used to encapsulate the one or more die stacks. An outer mold material having a higher Young's modulus is used to encapsulate the inner mold material.

Example embodiment 20: The method of embodiment 19, further comprising: forming the inner mold material having the low Young's modulus of approximately 2500 MPa or less over a temperature range of −50° C. to 270° C.

Example embodiment 21: The method of embodiment 19, further comprising: forming the inner mold material such that the low Young's modulus ranges from approximately 1 to 500 MPa.

Example embodiment 22: The method of embodiment 19, further comprising: forming the inner mold material such that the low Young's modulus ranges from approximately 501 to 1500 MPa.

Example embodiment 23: The method of embodiment 19, further comprising: forming the inner mold material such that the low Young's modulus ranges from approximately 1501 to 2500 MPa.

Example embodiment 24: The method of embodiment 19, 20, 21, 22, or 23, wherein forming an inner mold material further comprises: patterning the inner mold material away from edges of the substrate to leave room for the outer mold material.

Example embodiment 25: The method of embodiment 19, 20, 21, 22, or 23, wherein forming an inner mold material further comprises: patterning the inner mold material to only cover individual ones of the one or more die stacks.

What is claimed is:

1. A semiconductor package, comprising:
a substrate having a first side and the second side, the second side comprising interconnect joints;
one or more die stacks over the first side of the substrate;
an inner mold material having a low Young's modulus of less than 2500 MPa encapsulating the one or more die stacks; and
an outer mold material having a higher Young's modulus encapsulating the inner mold material.

2. The semiconductor package of claim 1, wherein the low Young's modulus of the inner mold material is approximately 2500 MPa or less over a temperature range of −50° C. to 270° C.

3. The semiconductor package of claim 1, wherein the low Young's modulus of the inner mold material ranges from approximately 1 to 500 MPa.

4. The semiconductor package of claim 3, wherein the inner mold material improves solder joint reliability by approximately 10 times.

5. The semiconductor package of claim 1, wherein the low Young's modulus of the inner mold material ranges from approximately 501 to 1500 MPa.

6. The semiconductor package of claim 1, wherein the low Young's modulus of the inner mold material ranges from approximately 1501 to 2500 MPa.

7. The semiconductor package of claim 1, wherein the higher Young's modulus of the outer mold material is approximately at least 20,000 MPa.

8. The semiconductor package of claim 1, wherein the outer mold material is at least approximately 0.1 mm in thickness.

9. The semiconductor package of claim 1, wherein the inner mold material comprises one of: a photopolymeric photoresist, a photodecomposing photoresist, a photocrosslinking photoresist, a self-assembled monolayer photoresist, a die attach film, and a glob top compound.

10. A package system, comprising:
a printed circuit board;
a semiconductor package comprising:
a substrate having a first side and the second side, the second side comprising an array of solder balls to couple the semiconductor package to the printed circuit board;
one or more die stacks over the first side of the substrate;
an inner mold material having a low Young's modulus of less than 2500 MPa encapsulating the one or more die stacks; and
an outer mold material having a higher Young's modulus encapsulating the inner mold material.

11. The package system of claim 10, wherein the low Young's modulus of the inner mold material is approximately 2500 MPa or less over a temperature range of −50° C. to 270° C.

12. The package system of claim 10, wherein the low Young's modulus of the inner mold material ranges from approximately 1 to 500 MPa.

13. The package system of claim 12, wherein the inner mold material improves solder joint reliability by approximately 10 times.

14. The package system of claim 10, wherein the low Young's modulus of the inner mold material ranges from approximately 501 to 1500 MPa.

15. The package system of claim 10, wherein the low Young's modulus of the inner mold material ranges from approximately 1501 to 2500 MPa.

16. The package system of claim 10, wherein the higher Young's modulus of the outer mold material is approximately at least 20,000 MPa.

17. The package system of claim 10, wherein the outer mold material is at least approximately 0.1 mm in thickness.

18. The package system of claim 10, wherein the inner mold material comprises one of: a photopolymeric photoresist, a photodecomposing photoresist, a photocrosslinking photoresist, a self-assembled monolayer photoresist, a die attach film, and a glob top compound.

19. A method of fabricating a semiconductor package, the method comprising:
forming one or more die stacks over a first side of the substrate;
forming an inner mold material having a low Young's modulus of less than 2500 MPa to encapsulate the one or more die stacks; and
forming an outer mold material having a higher Young's modulus to encapsulate the inner mold material.

20. The method of claim 19, further comprising: forming the inner mold material having the low Young's modulus of approximately 2500 MPa or less over a temperature range of −50° C. to 270° C.

21. The method of claim 19, further comprising: forming the inner mold material such that the low Young's modulus ranges from approximately 1 to 500 MPa.

22. The method of claim 19, further comprising: forming the inner mold material such that the low Young's modulus ranges from approximately 501 to 1500 MPa.

23. The method of claim 19, further comprising: forming the inner mold material such that the low Young's modulus ranges from approximately 1501 to 2500 MPa.

24. The method of claim 19, wherein forming an inner mold material further comprises: patterning the inner mold material away from edges of the substrate to leave room for the outer mold material.

25. The method of claim 19, wherein forming an inner mold material further comprises: patterning the inner mold material to only cover individual ones of the one or more die stacks.
